(19) United States
(12) Patent Application Publication
(10) Pub. No.: US 2010/0117187 A1
(43) Pub. Date: May 13, 2010

(54) METHOD FOR FORMING GATE IN FABRICATING SEMICONDUCTOR DEVICE

(76) Inventor: Dae-Kyeun Kim, Gangnam-gu (KR)

Correspondence Address: SHERR & VAUGHN, PLLC, 620 HERNDON PARKWAY, SUITE 320, HERNDON, VA, 20170, US

(21) Appl. No.: 12/609,374

(22) Filed: Oct. 30, 2009

(30) Foreign Application Priority Data
Nov. 7, 2008 (KR) 10-2008-0110338

(51) Int. Cl. H01L 29/40; H01L 21/02; H01L 21/00

(52) U.S. Cl. 257/499; 438/597; 29/25.01; 257/E21.002; 257/E29.111

(57) ABSTRACT

In fabricating a semiconductor device, by forming gate electrode lines to meet a design rule with additional simple processes such as a masking process, an etching process and the like for securing an isolation space between the gate electrode lines according to the design rule, the method of embodiments can overcome a problem in the related gate forming process so that a chip size is increased and high mask quality is required since the process has to proceed in consideration of additional design guide rules B1, B2 and the like for the length of gate electrode lines in addition to a gate forming process margin.

The present application claims priority under 35 U.S.C. 119 to Korean Patent Application No. 10-2008-0110338 (filed on Nov. 07, 2008), which is hereby incorporated by reference in its entirety.

### BACKGROUND

In fabricating in a transistor, a process of forming a gate electrode by depositing and etching a material, such as polysilicon, has used a design rule to prevent the formation of a bridge between one gate and another, using optical proximity correction (OPC) and a high-graded photomask corresponding to OPC, etc.

FIGS. 1A and 1B are schematic views showing formation of active areas and gate electrodes according to a related design rule. First, FIG. 1A shows formation of active areas 100 and 102 using a design rule A1 defined in consideration of an electrical characteristic related to leakage between the active areas 100 and 102. In this case, as shown in FIG. 1B, if polysilicon for gate electrode lines 104 and 106 are formed on the two active areas and design guides B1 and B2 are additionally applied which are required in relation with a process characteristic rather than an electrical characteristic in consideration of a margin which can be guaranteed for a process, the design rule between the active areas is further extended from the existing A1 to A2. Here, B1 refers to a guideline to minimize an effect due to a rounded profile from an end of each of the active areas to an end of each of the gate electrode lines. B2 refers to a guideline to prevent a bridge between the two gate electrode lines.

In the above case, a final cell size is increased over the existing cell size due to an issue related to the process margin. This results in an increase in chip size, and hence decrease in a yield.

FIGS. 2A and 2B are schematic views for explaining problems which may occur when the above-mentioned gate formation-related process margin cannot be secured. FIG. 2A shows a bridge effect 108 between the gate electrode lines 104 and 106, which may occur when a photo process margin is not sufficient. FIG. 2B shows a round profile 110 which occurs due to characteristics of a photolithography process and an etching process when a gate electrode line is not sufficiently extended at an end of an active area. As shown in these figures, if the width of the gate electrode line 106 formed over the active area 102 is not uniform, a current flows in a narrow portion of the gate electrode line 106 before anywhere else, which may result in deterioration of performance of the semiconductor device.

### SUMMARY

Embodiments relate to a method for fabricating a semiconductor device, and more particularly, to a method for forming a gate in fabricating a semiconductor device, which is capable of securing a greater process margin applied in consideration of a process margin in a fabricating process rather than an electrical process margin in fabricating a semiconductor device, and reducing a chip size.

Embodiments relate to a method for forming a gate in fabricating a semiconductor device, which is capable of forming gate electrode lines in compliance with a design rule by adding simple processes, such as a masking process, an etching process and the like, for securing an isolation space between the gate electrode lines according to the design rule, thereby securing a greater process margin applied in consideration of a process margin in a fabricating process rather than an electrical process margin in fabricating a semiconductor device, and reducing a chip size.

Embodiments relate to a method for forming a gate in fabricating a semiconductor device, including: forming active areas such that the active areas are isolated from each other at a prescribed distance according to a particular design rule for manufacture of a semiconductor device; forming neighboring gate electrode lines on the active areas, respectively, wherein the gate electrode lines are formed to extend out of the active areas; forming a mask on the active areas, wherein the mask is used to form a minimum isolation space between the gate electrode lines according to the design rule; and etching the gate electrode lines using the mask such that each of the gate electrode lines extending out of the active areas has a prescribed length.

With the above-described configuration of embodiments, by forming gate electrode lines to meet a design rule with additional simple processes such as a masking process, an etching process and the like for securing an isolation space between the gate electrode lines according to the design rule, embodiments can overcome a problem in the related gate forming process that a chip size is increased and high mask quality is required since the process has to proceed in consideration of additional design guide rules B1, B2 and the like for the length of gate electrode lines in addition to a gate forming process margin. Accordingly, embodiments have an advantage of employment of a mask of lower quality, reduction of chip size, and hence decrease in production cost and great increase in productivity.

Embodiments relate to an apparatus configured to form active areas on a semiconductor substrate such that the active areas are isolated from each other at a prescribed distance according to a particular design rule for manufacture of a semiconductor device, form neighboring gate electrode lines over the active areas, wherein the gate electrode lines are formed to extend out of the active areas, form a mask over the active areas, wherein the mask is used to form a minimum isolation space between the gate electrode lines according to the design rule, and etch the gate electrode lines using the mask such that each of the gate electrode lines extending out of the active areas has a prescribed length.

### DRAWINGS

FIGS. 1A and 1B are views showing a related gate forming process.

FIGS. 2A and 2B are views showing an example of bridge and round profile which may occur in the related gate forming process.

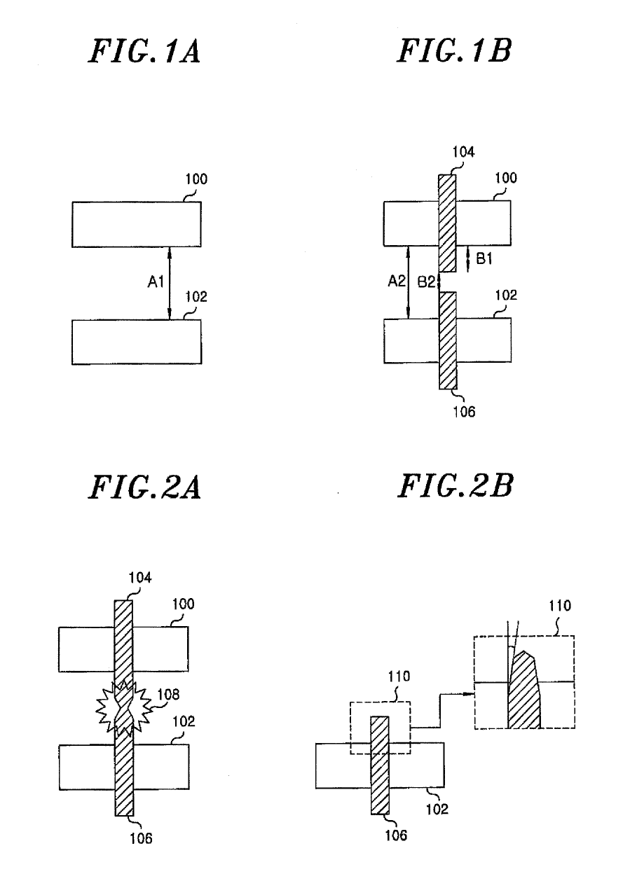

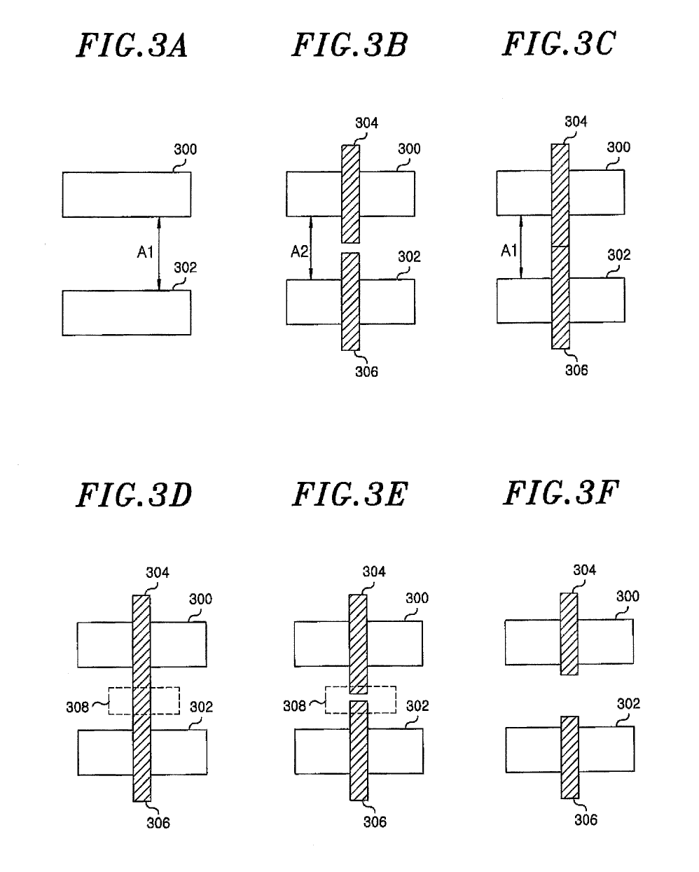

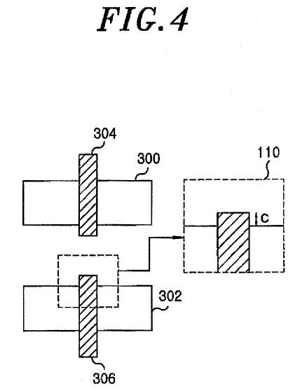

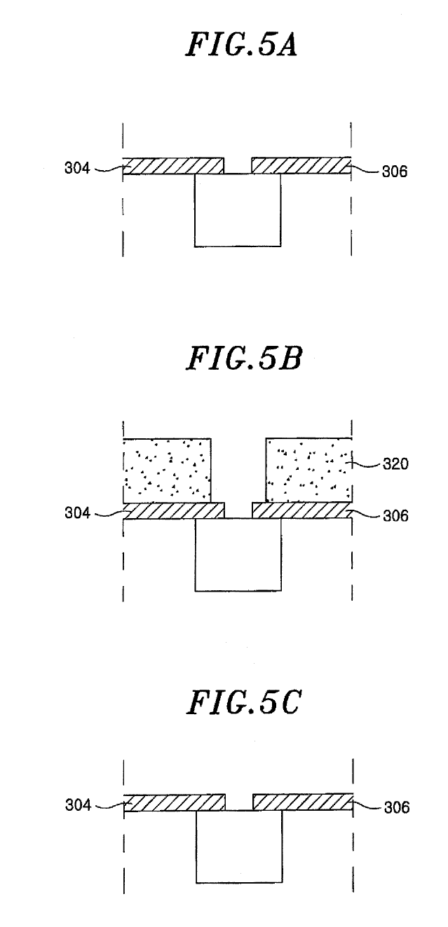

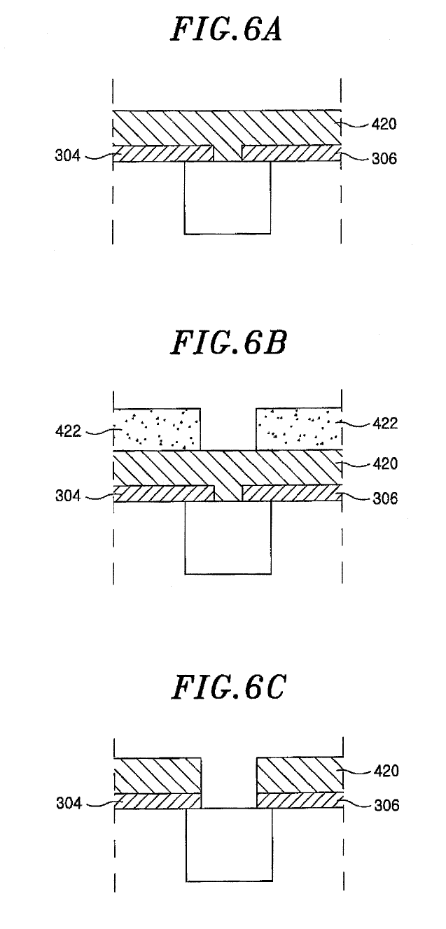

Example FIGS. 3A to 3F are views showing a gate forming process according to embodiments.

Example FIG. 4 is a view showing an gate electrode line etching process according to embodiments.

Example FIGS. 5A to 5C are views showing a masking process for forming gate electrode lines according to embodiments.

Example FIGS. 6A to 6C are views showing another masking process for forming gate electrode lines according to embodiments.

### DESCRIPTION

Embodiments relate to forming gate electrode lines in compliance with a design rule by adding simple processes, such as a masking process, an etching process and the like, for securing an isolation space between the gate electrode lines according to the design rule.

Example FIGS. 3A to 3F are views showing an exemplary gate forming process in fabricating a semiconductor device according to embodiments. Hereinafter, the gate forming process according to embodiments will be described in detail with reference to example FIGS. 3A to 3F. First, as shown in example FIG. 3A, active areas 300 and 302 may be formed in such a manner that a distance A1 there between is maintained according to a design guide rule related to a leakage between the active areas 300 and 302.

Subsequently, as shown in example FIG. 3B or 3C, while the gate electrode lines 304 and 306 may be formed to extend out of the active areas 300 and 302 according to a related gate electrode line extension rule, the gate electrode lines 300 and 302 may be formed without considering an isolation space for preventing a bridge from occurring between both ends of the gate electrode lines 300 and 302. Thus, as shown in example FIG. 3B or 3C, the gate electrode lines 304 and 306 extending out of the active areas may be formed to be very adjacent or bridged to each other.

Thereafter, as shown in example FIG. 3D or 3E, a photoresist mask 308 may be formed for etching the gate electrode lines 304 and 306 so that the isolation space between the gate electrode lines 304 and 306 is secured according to a design rule. In embodiments, the photoresist mask 308 can be automatically formed in a related mask forming process, and its size may be set such that a process margin value C, which may maximally reflect both a photo overlay process and an etching process guaranteed in a FAB process, can be secured, as shown in example FIG. 4.

Subsequently, as shown in example FIG. 3F, the photoresist mask 308 may be used to etch the two gate electrode lines 304 and 306 formed to extend out of the active areas, so that the isolation space can be secured to meet the design rule for preventing a bridge from occurring between the gate electrode lines.

Example FIGS. 5A to 5C show a process of forming a photoresist mask and a process of forming gate electrode lines using the photoresist mask. First, as shown in example FIG. 5A, the gate electrode lines 304 and 306 may be formed through a photolithography process and an etching process. As shown in example FIG. 5B, a photoresist mask 320 may be formed over the gate electrode lines 304 and 306 to secure an isolation space for preventing a bridge from occurring between the two gate electrode lines 304 and 306.

In embodiments, for the formation of the photoresist mask 320, the photoresist mask shown in example FIG. 5B may be formed by applying a photoresist film over the entire surface of a semiconductor substrate, including the gate electrode lines 304 and 306, and then patterning the photoresist film. Subsequently, as shown in example FIG. 5C, the photoresist mask 320 may be used to etch the gate electrode lines 304 and 306 so that an isolation space can be secured to meet the design rule for preventing a bridge from occurring between the gate electrode lines 304 and 306.

Example FIGS. 6A to 6C show a process of forming a photoresist mask and a process of forming gate electrode lines using the photoresist mask after a dielectric material film is formed over gate electrode lines. First, as shown in example FIG. 6A, a dielectric material film 420 may be deposited over the gate electrode lines 304 and 306 formed through a photolithography process and an etching process. Then, as shown in example FIG. 6B, a photoresist mask 422 is formed over the gate electrode lines 304 and 306 through the dielectric material film 420 to secure an isolation space for preventing a bridge from occurring between the two gate electrode lines 304 and 306.

In embodiments, to form the photoresist mask 420, the photoresist mask shown in example FIG. 6B may be formed by applying a photoresist film over the entire surface of a semiconductor substrate, including the gate electrode lines 304 and 306, and then patterning the photoresist film.

Subsequently, as shown in example FIG. 6C, the photoresist mask 422 may be used to etch the dielectric material film 420 and the gate electrode lines 304 and 306 so that an isolation space can be secured to meet the design rule for preventing a bridge from occurring between the gate electrode lines 304 and 306.

As described above, by forming gate electrode lines to meet a design rule with additional simple processes such as a masking process, an etching process and the like for securing an isolation space between the gate electrode lines according to the design rule, embodiments can overcome a problem in the related gate forming process that a chip size is increased and high mask quality is required since the process has to proceed in consideration of additional design guide rules B1, B2 and the like for the length of gate electrode lines in addition to a gate forming process margin.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming active areas on a semiconductor substrate such that the active areas are isolated from each other at a prescribed distance according to a particular design rule for manufacture of a semiconductor device;
forming neighboring gate electrode lines over the active areas, wherein the gate electrode lines are formed to extend out of the active areas;
forming a mask over the active areas, wherein the mask is used to form a minimum isolation space between the gate electrode lines according to the design rule; and
etching the gate electrode lines using the mask such that each of the gate electrode lines extending out of the active areas has a prescribed length.

2. The method of claim 1, wherein forming neighboring gate electrode lines includes forming the gate electrode lines without a limitation to length of the gate electrode lines extending out of the active areas.

3. The method of claim 1, wherein forming neighboring gate electrode lines includes forming the gate electrode lines without applying an isolation space between the neighboring gate electrode lines extending out of the active areas according to the design rule.

4. The method of claim 1, wherein forming a mask includes:
applying a photoresist film over the entire surface of a semiconductor substrate over which the gate electrode lines are formed; and
forming the mask by patterning the photoresist film such that an etching area for formation of the isolation space between the gate electrode lines is opened.

5. The method of claim 1, wherein etching the gate electrode lines includes setting a prescribed length of the gate electrode lines extending out of the active areas to meet a process margin in a semiconductor device fabricating process subsequent to etching the gate electrode lines.

6. The method of claim 5, wherein the fabricating process subsequent to etching the gate electrode lines is a process of forming an etching bias for fabrication of the semiconductor device.

7. The method of claim 5, wherein the fabricating process subsequent to etching the gate electrode lines is a process of forming an active area.

8. The method of claim 5, wherein the fabricating process subsequent to etching the gate electrode lines is a process of forming a gate electrode.

9. The method of claim 5, wherein the fabricating process subsequent to etching the gate electrode lines is a process of forming a photo overlay.

10. An apparatus comprising:
active areas in a semiconductor substrate isolated from each other at a prescribed distance according to a particular design rule for manufacturing of a semiconductor device;
gate electrode lines formed over the active areas and which extend out of the active areas; and
a mask formed over the active areas,
wherein the mask is used to form a minimum isolation space between the gate electrode lines according to the design rule.

11. The apparatus of claim 10, wherein the gate electrode lines are formed without a limitation to length of the gate electrode lines extending out of the active areas.

12. The apparatus of claim 10, wherein the gate electrode lines are formed without applying an isolation space between the neighboring gate electrode lines extending out of the active areas according to the design rule.

13. The apparatus of claim 10, wherein the mask is formed by applying a photoresist film over the entire surface of a semiconductor substrate over which the gate electrode lines are formed and patterning the photoresist film such that an etching area for formation of the isolation space between the gate electrode lines is opened.

14. The apparatus of claim 10, wherein, after etching the gate electrode lines, a prescribed length of the gate electrode lines extending out of the active areas is set to meet a process margin in a semiconductor device fabricating process subsequent to etching the gate electrode lines.

15. An apparatus configured to:
form active areas on a semiconductor substrate such that the active areas are isolated from each other at a prescribed distance according to a particular design rule for manufacture of a semiconductor device;
form neighboring gate electrode lines over the active areas, wherein the gate electrode lines are formed to extend out of the active areas;
form a mask over the active areas, wherein the mask is used to form a minimum isolation space between the gate electrode lines according to the design rule; and
etch the gate electrode lines using the mask such that each of the gate electrode lines extending out of the active areas has a prescribed length.

16. The apparatus of claim 15, configured to form neighboring gate electrode lines by forming the gate electrode lines without a limitation to length of the gate electrode lines extending out of the active areas.

17. The apparatus of claim 15, configured to form neighboring gate electrode lines by forming the gate electrode lines without applying an isolation space between the neighboring gate electrode lines extending out of the active areas according to the design rule.

18. The apparatus of claim 15, configured to form a mask by:
applying a photoresist film over the entire surface of a semiconductor substrate over which the gate electrode lines are formed; and
forming the mask by patterning the photoresist film such that an etching area for formation of the isolation space between the gate electrode lines is opened.

19. The apparatus of claim 15, configured to etch the gate electrode lines by setting a prescribed length of the gate electrode lines extending out of the active areas to meet a process margin in a semiconductor device fabricating process subsequent to etching the gate electrode lines.

20. The apparatus of claim 19, wherein the fabricating process subsequent to etching the gate electrode lines is a process of forming an active area.
